(19) United States
(12) Patent Application Publication
(10) Pub. No.: US 2020/0233098 A1
(43) Pub. Date: Jul. 23, 2020

(54) LIGHT-RECEIVING DEVICE

(71) Applicant: SONY SEMICONDUCTOR SOLUTIONS CORPORATION, KANAGAWA (JP)

(72) Inventors: KATSUJI MATSUMOTO, KANAGAWA (JP); TAKAHIRO IGARASHI, KANAGAWA (JP); TAKAHIRO SONODA, KAGOSHIMA (JP)

(21) Appl. No.: 16/482,878

(22) PCT Filed: Feb. 8, 2018
(86) PCT No.: PCT/JP2018/004288

§ 371 Date: Aug. 1, 2019

(30) Foreign Application Priority Data
Feb. 22, 2017 (JP) 2017-030742

(51) Int. Cl. G01T 1/105; H01L 27/146

(52) U.S. Cl. CPC G01T 1/105; H01L 27/146

(57) ABSTRACT

The present technology relates to a light-receiving device that makes it possible to simplify readout from a plurality of pixels and a process after the readout, without deteriorating light receiving sensitivity and characteristics in resolution. A plurality of unit elements is disposed above a substrate, each of the unit elements including a plurality of pixels disposed in m number of rows and n number of columns, and a readout section that sequentially reads out signals from a plurality of pixels disposed in a column direction among the plurality of pixels. The number of readout sections is at least the same as the number of columns. The readout section includes a QV amplifier. The present technology is applicable to the light-receiving device that detects radiation.

### TECHNICAL FIELD

The present technology relates to a light-receiving device. For example, the present technology relates to a light-receiving device that is suitably applicable to a device for detecting radiation such as an α ray, a β ray, a γ ray, or an X ray.

### BACKGROUND ART

Various kinds of imaging devices have been proposed as imaging devices including photoelectric conversion elements in respective pixels (image capturing pixels). For example, Patent Literature 1 describes a back-illuminated imaging apparatus as an example of such imaging devices including the photoelectric conversion elements.

In addition, Patent Literature 2 proposes a radiation imaging device as an example of the imaging device including the photoelectric conversion elements. To reduce radiation exposure, an active light-receiving device is necessary. The active light-receiving device includes amplifier circuits in pixels. The pixels including amplifiers enables reduction in noise.

In addition, sensitivity is also an important factor. Improvement in sensitivity and reduction in noise result in reduction in radiation exposure. It is necessary for a radiation imaging device to have a size corresponding to sizes of respective parts of a body of an imaging target person. For example, a maximum size of 40 cm×30 cm or more is necessary. Therefore, a technology of enlarging the size of a high-performance sensor is also necessary.

### CITATION LIST

### Patent Literature

Patent Literature 1: JP 2014-192348A

Patent Literature 2: JP 2016-46336A

### DISCLOSURE OF INVENTION

### Technical Problem

In general, with regard to pixels disposed in array in a row direction and a column direction, output lines are formed for respective columns, and the pixels are simultaneously read out in a perpendicular direction.

Among the light-receiving devices, it is desired for an (active) low-noise light-receiving device that demands low dose of radiation to narrow a pixel pitch and achieve high resolution. In addition, to achieve the low noise, it is necessary to dispose a circuit near the pixel. Such a light-receiving device has a layout in which a light-receiving area and a circuit area are lined up with respect to a light-receiving surface. Therefore, the fill factor decreases due to the circuit area, and light reception sensitivity may decrease. In other words, there is a tradeoff relation between resolution and light reception sensitivity due to the pixel area and the circuit area.

In addition, although the readout is simple, it is difficult to achieve the global shutter because of dynamic range and linearity.

On the other hand, image sensors in which IC elements are stacked have been proposed. In the image sensors, a plurality of photoelectric conversion elements shares an amplifier or the like. For example, in the case where four pixels share one amplifier or the like, a pixel readout sequence proceeds in a zig-zag manner. Therefore, it is necessary to change the order of read-out numerical values, and the sequence may be complicated.

The present technology has been made in view of the above described situations. According to the present technology, it is possible to prevent a process or the like after readout from being complicated even in the case of a sharing structure in which a plurality of pixels shares an amplifier or the like.

### Solution to Problem

According to an aspect of the present technology, a light-receiving element includes a plurality of unit elements disposed above a substrate, each of the unit elements including a plurality of pixels disposed in m number of rows and n number of columns, and a readout section that sequentially reads out signals from a plurality of pixels disposed in a column direction among the plurality of pixels. The number of readout sections is at least the same as the number of columns.

In the light-receiving element according to the aspect of the present technology, a plurality of unit elements is disposed above a substrate, each of the unit elements including a plurality of pixels disposed in m number of rows and n number of columns, and a readout section configured to sequentially read out signals from a plurality of pixels disposed in a column direction among the plurality of pixels. In addition, the number of readout sections is at least the same as the number of columns.

Note that, the light-receiving device may be an independent device, or may be an internal block included in a device.

### Advantageous Effects of Invention

According to an aspect of the present technology, a process or the like after readout does not get complicated even in the case of the sharing structure in which a plurality of pixels shares an amplifier or the like.

Note that, the effects described herein are not necessarily limited and may be any of the effects described in the present disclosure.

### BRIEF DESCRIPTION OF DRAWINGS

FIG. 1 is a block diagram illustrating a configuration example of a device including a light-receiving device according to the present technology.

FIG. 2 is a diagram illustrating a configuration of a light-receiving device according to an embodiment of the present technology.

FIG. 3 is a diagram for describing unit elements disposed above a substrate.

FIG. 4 is a diagram for describing a configuration of the unit element.

FIG. 5 is a diagram for describing order of reading out signals from pixels.

FIG. 6 is a diagram for describing another configuration of the unit element.

FIG. 7 is a diagram for describing another configuration of the unit element.

FIG. 8 is a cross-sectional view of the unit element.

FIG. 9 is a circuit diagram of the unit element.

FIG. 10 is diagram for describing wiring and terminals of a substrate.

FIG. 11 is diagram for describing wiring and terminals of a substrate.

FIG. 12 is a diagram for describing the number of terminals of a substrate.

FIG. 13 is a diagram for describing a configuration of a transistor.

FIG. 14 is a diagram for describing noise reduction.

### MODE(S) FOR CARRYING OUT THE INVENTION

An embodiment for implementing the present technology (hereinafter, referred to as an embodiment) will be described below.

### <Configuration Example of Radiation Imaging Device>

The present technology is applicable to a device for detecting radiation such as an α ray, a β ray, a γ ray, or an X ray. In addition, the present technology is applicable to such a device that is a light-receiving device for receiving radiation light.

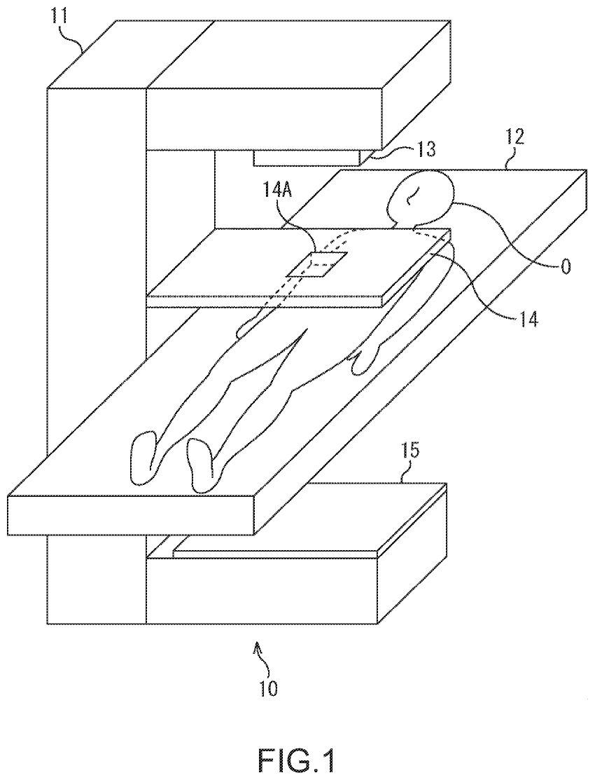

FIG. 1 is a block diagram illustrating a configuration example of a radiation imaging device including a light-receiving device according to an embodiment of the present technology. Note that, the description will be given while the radiation imaging device is used as an example. However, the present technology is also applicable to an X-ray machine, a CT scanner, a line sensor, and the like that include a radiation detector.

A radiation imaging device 10 in FIG. 1 includes an arm 11, an imaging table 12, a multipoint parallel X-ray source 13, a shield plate 14, and an imaging section 15. The radiation imaging device 10 radiates X rays to an object O (a person in the example of FIG. 1) on the imaging table 12, and captures an image.

Specifically, the arm 11 of the radiation imaging device 10 includes a micro processing unit (MPU) and various kinds of processing circuits (not illustrated) therein, and controls the multipoint parallel X-ray source 13. In addition, the arm 11 holds the imaging table 12, the multipoint parallel X-ray source 13, the shield plate 14, and the imaging section 15. The imaging table 12 is a table on which the object O is put.

For example, the multipoint parallel X-ray source 13 includes a plurality of X-ray tubes and a plurality of collimators. The multipoint parallel X-ray source 13 emits parallel X-ray beams to the imaging table 12 under the control of the arm 11. For example, the shield plate 14 contains metal capable of blocking the X-rays such as lead or iron, and the shield plate 14 is provided between the multipoint parallel X-ray source 13 and the imaging table 12. The object O is sandwiched between the imaging table 12 and the shield plate 14.

The shield plate 14 has an opening 14A. Via the opening 14A, the object O is irradiated with X-rays emitted by the multipoint parallel X-ray source 13. Therefore, the object O is placed on the imaging table 12 in a manner that the position of the opening 14A corresponds to the position of the imaging target.

The imaging section 15 includes an X-ray CMOS image sensor. The imaging section 15 converts the x-rays radiated from the multipoint parallel X-ray source 13 via the opening 14A into visible light, and captures an image. The imaging section 15 holds the image obtained as a result of the image capturing, or transmits the image to another device through a network (not illustrated).

### <Configuration Example of Light-Receiving Device>

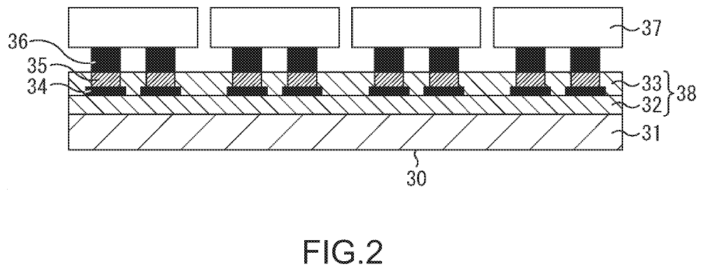

FIG. 2 is a cross-sectional view of a configuration of a light-receiving device of the imaging section 15 illustrated in FIG. 1. A light-receiving device 30 illustrated in FIG. 2 detects radiation such as an α ray, a β ray, a γ ray, or an X ray. The light-receiving device 30 is usable as an indirect-conversion-type radiation detector. The indirect conversion type means a method of converting radiation into visible light and then converting it into an electric signal.

The light-receiving device 30 has a configuration in which a substrate 31, an insulating film 32, an insulating film 33, a wiring layer 34, under-barrier metal (UBM) 35, a solder layer 36, and a unit element 37 are stacked, and the insulating film 32 to the solder layer 36 serve as a wiring substrate 38.

For example, the substrate 31 contains glass, quartz, an organic substrate, or the like. Above the substrate 31, a plurality of the unit elements 37 is formed and connected. For example, the substrate 31 is connected to a power source, ground, and a terminal of a reference power source that are lined up in a vertical direction. In addition, the substrate 31 includes wiring for extracting a signal to an outside. Wiring lines that are lined up in a lateral direction are wiring lines for supplying various kinds of control signals.

In the light-receiving device 30, the plurality of unit elements 37 is mounted above the wiring substrate 38 via the UBM 35 and the solder layer 36. The unit element 37 can contain silicon.

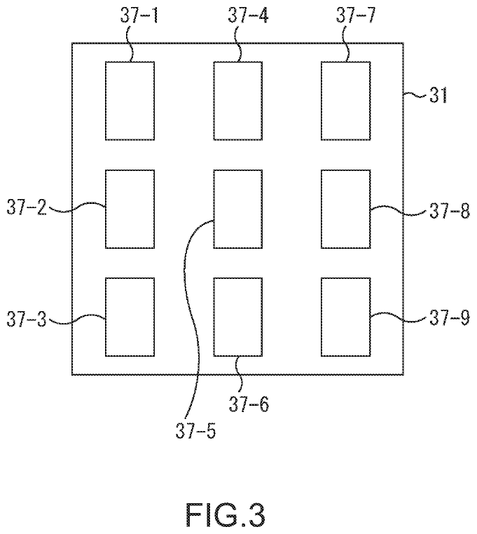

When viewed from the light-receiving side (the unit element 37 side), the light-receiving device 30 includes the plurality of unit elements 37 above the substrate 31 above the substrate 31 as illustrated in FIG. 3. In the example illustrated in FIG. 3, nine unit elements 37 which are unit elements 37-1 to 37-9 are disposed.

The imaging section 15 of the radiation imaging device 10 illustrated in FIG. 1 has a size suitable for sizes of respective parts of a human body that is an imaging target. Therefore, for example, the imaging section 15 is configured to have a size of approximately 40 cm×30 cm.

The unit element 37 may have the size of approximately 40 cm×30 cm. However, it is difficult to manufacture the unit element 37 with the size of approximately 40 cm×30 cm because the unit element 37 with the size of approximately 40 cm×30 cm does not have enough strength. Therefore, for example, the following description will be given with reference to a case where the imaging section 15 with the size of approximately 40 cm×30 cm is obtained by forming the unit elements 37 with sizes enough to have sufficient strength and disposing the plurality of unit elements 37 above the substrate 31.

### <Configuration Example of Unit Element>

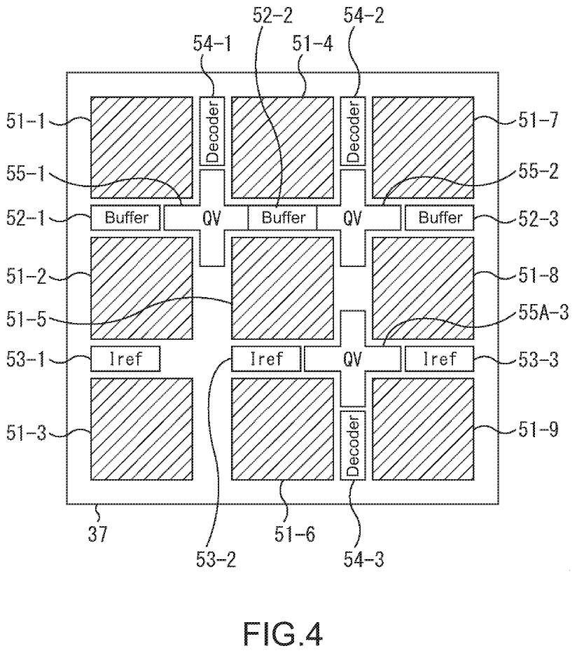

The unit element 37 is configured as illustrated in FIG. 4. FIG. 4 is a plan view of the unit element 37 when viewed from the substrate 31 side. The unit element 37 illustrated in FIG. 4 includes nine (=3×3) pixels 51.

The single unit element 37 includes the plurality of pixels 51. The number of pixels 51 included in the single unit element 37 is not limited to nine. Here, the description will be given with reference to an example in which the single unit element 37 includes the nine pixels 51. However, the number of pixels 51 is not limited to nine. The present technology is applicable to a unit element 37 including a plurality of the pixels 51.

In addition, the description will be given on the assumption that the nine pixels are disposed in array of 3 rows×3 columns. Alternatively, the present technology is also applicable to a unit element 37 in which pixels are disposed in m number of rows and n number of columns. In addition, m is three or more, and n is two or more. In other words, the present technology is applied to a case where three or more pixels are disposed in a vertical direction (perpendicular direction), and two or more pixels are disposed in a lateral direction (horizontal direction).

The unit element 37 illustrated in FIG. 4 includes the pixels 51-1 to 51-9, buffers 52-1 to 52-3, constant-current supplies (Iref) 53-1 to 53-3, decoders 54-1 to 54-3, and QV amplifiers 55-1 to 55-3. Hereinafter, the pixels 51-1 to 51-9 are simply referred to as pixels 51 in a case where it is not necessary to particularly distinguish the pixels 51-1 to 51-9. In addition, the same applies to other structural elements.

The pixel 51 includes a photodiode, and receives incident light. The buffer 52 temporarily holds a signal representing an amount of electric charge accumulated in the pixel 51 read out via the QV amplifier 55, and outputs the signal to a processor (not illustrated) in a later stage. The QV amplifier 55 is a charge/voltage conversion amplifier, and includes a conversion circuit that converts photocurrent of the pixel 51 into a voltage signal. The QV amplifier 55 performs processes such as a process of selecting a pixel 51, from which the photocurrent is to be read out, and a process of resetting the pixel 51.

The decoder 54 controls operation of the QV amplifier 55. The constant-current supply 53 converts current or voltage to be supplied, into stable current or voltage, and supplies it to respective structural elements of the unit element 37.

The unit element 37 includes the plurality of pixels 51 and a readout section that reads out signals from the pixels 51. The readout section includes the QV amplifier 55 and the buffer 52. The QV amplifier 55 includes a conversion circuit that converts photocurrent of the pixel 51 into a voltage signal, and the buffer 52 is connected to an output side of the conversion circuit. In addition, the unit element 37 includes the decode 54 for controlling the readout section.

In the unit element 37 illustrated in FIG. 4, three pixels 51 share the single buffer 52, constant-current supply 53, decoder 54, and QV amplifier 55.

In the case where the pixels 51 do not share the structural elements, the buffer 52, constant-current supply 53, decoder 54, and QV amplifier 55 are prepared for each pixel 51. Therefore, there is a possibility that a region in which the buffer 52, the constant-current supply 53, the decoder 54, and the QV amplifier 55 are disposed becomes large and a region for the pixel 51 becomes small in the case where the size of the unit element 37 is limited. Accordingly, there is a possibility that sensitivity decreases.

When the unit element 37 is configured as illustrated in FIG. 4 in a manner that the three pixels 51 share the buffer 52, the constant-current supply 53, the decoder 54, and the QV amplifier 55, it is possible to reduce the number of buffers 52, constant-current supplies 53, decoders 54, and QV amplifiers 55 that have to be disposed in the unit element 37. When the number of them is reduced, it is possible to enlarge the region for the pixels 51. This enables sensitivity to be improved (maintained).

In addition, since the number of buffers 52, constant-current supplies 53, decoders 54, and QV amplifiers 55 that have to be disposed in the unit element 37 is reduced, it is also possible to enlarge regions allocated to the respective structural elements in the unit element 37. In addition, since the buffer 52, the constant-current supply 53, the decoder 54, and the QV amplifier 55 are configured to be shared, it is possible to reduce the number of terminals that have to be provided above the substrate 31. As described later, it is also possible to obtain effects of improving reliability, reducing noise, and the like.

In the unit element 37 illustrated in FIG. 4, the pixel 51-1, the pixel 51-2, and the pixel 51-3 disposed in the vertical direction (perpendicular direction, column direction) are configured to share the buffer 52-1, the constant-current supply 53-1, the decoder 54-1, and the QV amplifier 55-1.

In addition, in the unit element 37 illustrated in FIG. 4, the pixel 51-4, the pixel 51-5, and the pixel 51-6 disposed in the vertical direction are configured to share the buffer 52-2, the constant-current supply 53-2, the decoder 54-2, and the QV amplifier 55-2.

In addition, in the unit element 37 illustrated in FIG. 4, the pixel 51-7, the pixel 51-8, and the pixel 51-9 disposed in the vertical direction are configured to share the buffer 52-3, the constant-current supply 53-3, the decoder 54-3, and the QV amplifier 55-3.

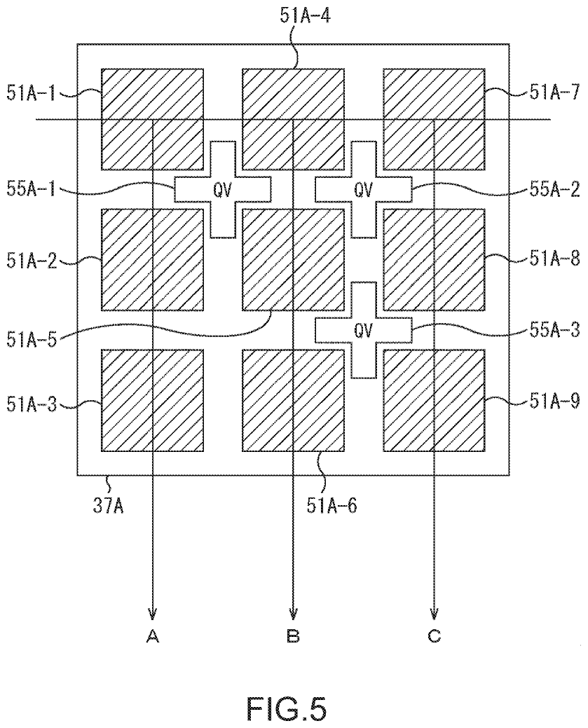

As described above, the plurality of pixels 51 disposed in the vertical direction is configured to share the buffer 52, the constant-current supply 53, the decoder 54, and the QV amplifier 55. Therefore, it is possible to sequentially read out signals from the pixels 51 in the vertical direction. Description thereof will be given with reference to FIG. 5.

FIG. 5 is a diagram illustrating only the pixels 51 and the QV amplifiers 55 in the unit element 37 illustrated in FIG. 4. In a unit element 37A including nine (=3×3) pixels 51A illustrated in FIG. 5, a QV amplifier 55A-1 reads out a signal from the pixel 51A-1. Next, the QV amplifier 55A-1 reads out a signal from the pixel 51A-2 disposed below the pixel 51A-1 in the perpendicular direction. Next, the QV amplifier 55A-1 reads out a signal from the pixel 51A-3 disposed below the pixel 51A-2 in the perpendicular direction.

In a similar way, a QV amplifier 55A-2 reads out a signal from the pixel 51A-4, reads out a signal from the pixel 51A-5 disposed below the pixel 51A-4 in the perpendicular direction, and then reads out a signal from the pixel 51A-6 disposed below the pixel 51A-5 in the perpendicular direction.

In addition, in a similar way, a QV amplifier 55A-3 reads out a signal from the pixel 51A-7, reads out a signal from the pixel 51A-8 disposed below the pixel 51A-7 in the perpendicular direction, and then reads out a signal from the pixel 51A-9 disposed below the pixel 51A-8 in the perpendicular direction.

As described above, the signals are sequentially read out from the pixels 51 disposed in the perpendicular direction. Since the signals are read out in order of the pixels 51 arrayed in the perpendicular direction as described above, it is not necessary to perform a process of changing the order of signals (numerical values) or the like as the process in the later stage. This enables the process in the later stage to be simplified.

For example, as a comparative example, it is assumed that the QV amplifier 55A-1 is shared by the pixel 51A-1, the pixel 51A-2, the pixel 51A-4, and the pixel 51A-5. In this case, 2x2 number of pixels 51A share the QV amplifier 55A-1. In such a case, the QV amplifier 55A-1 reads out signals from the pixel 51A-1, the pixel 51A-4, the pixel 51A-2, and the pixel 51A-5 in this order.

When the signals are read out in the above-described order, the pixel readout sequence proceeds in a zig-zag manner. Therefore, it is necessary to change the order of numerical values in a process after the readout, and there is a possibility that the sequence gets complicated. However, according to the present technology, as described above, it is possible to provide a pixel readout sequence capable of reading out signals from pixels only in the perpendicular direction. Therefore, it is not necessary to change the order of numerical values in the process, and it is possible to prevent the readout sequence from getting complicated.

With reference to FIG. 4 again, four (=2×2) pixels 51 are disposed, and the QV amplifier 55 is disposed at a crossing surrounded by the four pixels 51.

In general, the crossing means roads that intersect with each other in a cross shape. Here, the wording “crossing” means a part (region) where paths intersect with each other on the assumption that a region between two pixels 51 is treated as a path.

In addition, here, the crossing is the region including a center of a region in which the four (=2×2) pixels 51 are disposed, and the crossing is the region other than the pixels 51.

In the unit element 37 illustrated in FIG. 4, the QV amplifier 55-1 is disposed at a crossing surrounded by the pixel 51-1, the pixel 51-2, the pixel 51-4, and the pixel 51-5. In a similar way, the QV amplifier 55-2 is disposed at a crossing surrounded by the pixel 51-4, the pixel 51-5, the pixel 51-7, and the pixel 51-8. In a similar way, the QV amplifier 55-3 is disposed at a crossing surrounded by the pixel 51-5, the pixel 51-6, the pixel 51-8, and the pixel 51-9.

As described above, the QV amplifier 55 is disposed at the crossing surrounded by the four (=2×2) pixels 51. The crossing is a wider region than the region (path) between the pixels 51. The QV amplifier 55 is disposed in such a wider region.

The QV amplifier 55 tends to have a large circuit size because the QV amplifier 55 includes a plurality of transistors therein. Therefore, it is possible to effectively dispose the QV amplifiers 55 in the unit element 37 when such QV amplifiers 55 are disposed at the crossing.

In addition, since the QV amplifier 55 is disposed at the crossing, it is possible to dispose circuits other than the QV amplifier 55 such as the buffer 52, the constant-current supply 53, and the decoder 54 in the regions between the pixels (regions serving as the paths). Therefore, it is also possible to enlarge regions allocated to the circuits other than the QV amplifier 55.

### <Another Configuration of Unit Element>

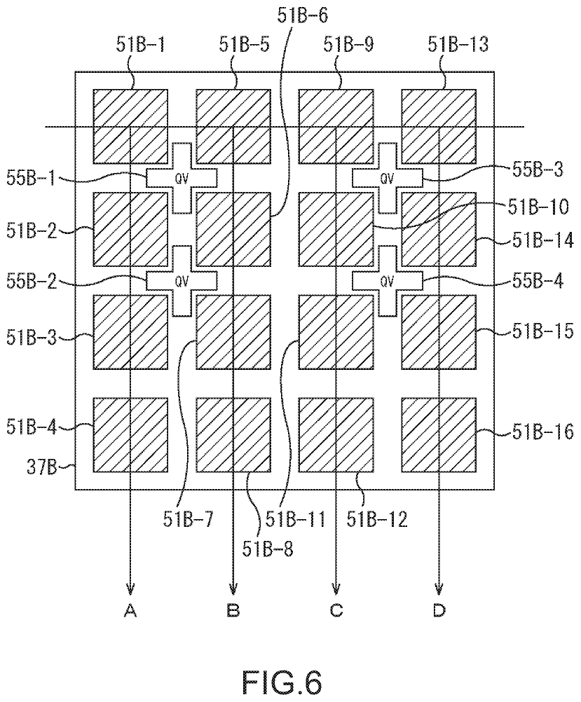

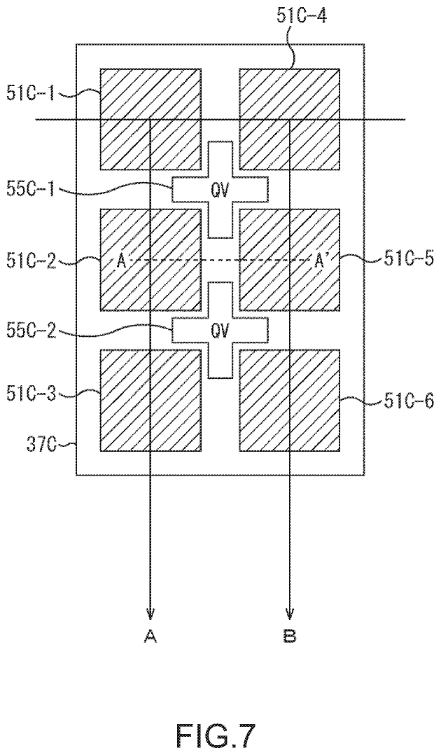

FIG. 4 and FIG. 5 illustrate the example in which the pixels 51 are disposed in the unit element 37 in the 3×3 manner. However, the description is not limited to the 3×3 pixel arrangement. For example, the present technology is also applicable to configurations illustrated in FIG. 6 and FIG. 7.

FIG. 6 illustrates an example in which 16 (=4×4) pixels 51B are disposed in a unit element 37B.

A QV amplifier 55B-1 is disposed at a crossing surrounded by four (=2×2) pixels which are a pixel 51B-1, a pixel 51B-2, a pixel 51B-5, and a pixel 51B-6. The QV amplifier 55B-1 is shared by the pixel 51B-1, the pixel 51B-2, a pixel 51B-3, and a pixel 51B-4 disposed in the perpendicular direction.

The QV amplifier 55B-1 reads out signals from the pixel 51B-1, the pixel 51B-2, the pixel 51B-3, and the pixel 51B-4 in this order, the pixels being disposed in the perpendicular direction.

A QV amplifier 55B-2 is disposed at a crossing surrounded by four (=2×2) pixels which are the pixel 51B-2, the pixel 51B-3, the pixel 51B-6, and a pixel 51B-7. The QV amplifier 55B-2 is shared by the pixel 51B-5, the pixel 51B-6, the pixel 51B-7, and a pixel 51B-8 disposed in the perpendicular direction.

The QV amplifier 55B-2 reads out signals from the pixel 51B-5, the pixel 51B-6, the pixel 51B-7, and the pixel 51B-8 in this order, the pixels being disposed in the perpendicular direction.

A QV amplifier 55B-3 is disposed at a crossing surrounded by four (=2×2) pixels which are a pixel 51B-9, a pixel 51B-10, a pixel 51B-13, and a pixel 51B-14. The QV amplifier 55B-3 is shared by the pixel 51B-9, the pixel 51B-10, a pixel 51B-11, and a pixel 51B-12 disposed in the perpendicular direction.

The QV amplifier 55B-3 reads out signals from the pixel 51B-9, the pixel 51B-10, the pixel 51B-11, and the pixel 51B-12 in this order, the pixels being disposed in the perpendicular direction.

A QV amplifier 55B-4 is disposed at a crossing surrounded by four (=2×2) pixels which are the pixel 51B-10, the pixel 51B-11, the pixel 51B-14, and a pixel 51B-15. The QV amplifier 55B-4 is shared by the pixel 51B-13, the pixel 51B-14, the pixel 51B-15, and a pixel 51B-16 disposed in the perpendicular direction.

The QV amplifier 55B-4 reads out signals from the pixel 51B-13, the pixel 51B-14, the pixel 51B-15, and the pixel 51B-16 in this order, the pixels being disposed in the perpendicular direction.

As described above, even in the case of the unit element 37B including the 16 (=4×4) pixels 51B, the QV amplifier 55B is shared in a manner that signals are sequentially read out from the pixels 51B disposed in the perpendicular direction (column direction). This enables a sequence after reading out the signals to be simplified.

Note that, the arrangement positions of the QV amplifiers 55B illustrated in FIG. 6 are a mere example. The present technology is not limited thereto. For example, it is also possible to dispose the QV amplifier 55B-2 at a crossing on the right side of the QV amplifier 55B-1 (a crossing surrounded by four (=2×2) pixels which are the pixel 51B-5, the pixel 51B-6, the pixel 51B-9, and the pixel 51B-10).

In addition, for example, it is also possible to dispose the QV amplifier 55B-2 at a crossing (a crossing surrounded by four (=2×2) pixels which are the pixel 51B-3, the pixel 51B-4, the pixel 51B-7, and the pixel 51B-8) that is below the QV amplifier 55B-1 with one crossing interposed therebetween.

As described above, the QV amplifiers 55B may be disposed at neighboring crossings, or at crossings disposed with one or more crossing interposed therebetween.

In addition, with reference to FIG. 7, another configuration of the unit element 37 will be described. FIG. 7 illustrates an example in which six (=2×3) pixels 51C are disposed in a unit element 37C.

A QV amplifier 55C-1 is disposed at a crossing surrounded by four (=2×2) pixels which are a pixel 51C-1, a pixel 51C-2, a pixel 51C-4, and a pixel 51C-5. The QV amplifier 55C-1 is shared by the pixel 51C-1, the pixel 51C-2, and a pixel 51C-3 disposed in the perpendicular direction.

The QV amplifier 55C-1 reads out signals from the pixel 51C-1, the pixel 51C-2, and the pixel 51C-3 in this order, the pixels being disposed in the perpendicular direction.

A QV amplifier 55C-2 is disposed at a crossing surrounded by four (=2×2) pixels which are the pixel 51C-2, the pixel 51C-3, a pixel 51C-5, and a pixel 51C-6. The QV amplifier 55C-2 is shared by the pixel 51C-4, the pixel 51C-5, and the pixel 51 C-6 disposed in the perpendicular direction.

The QV amplifier 55C-2 reads out signals from the pixel 51C-4, the pixel 51C-5, and the pixel 51C-6 in this order, the pixels being disposed in the perpendicular direction.

As described above, even in the case of the unit element 37C including the six (=2×3) pixels 51C, the QV amplifier 55C is shared in a manner that signals are sequentially read out from the pixels 51C disposed in the perpendicular direction (column direction). This makes it possible to simplify a sequence after reading out the signals.

The present technology is applicable to the case where the same number of pixels are disposed in the row direction and the column direction (horizontal direction and perpendicular direction) like the unit element 37A illustrated in FIG. 5 and the unit element 37B illustrated in FIG. 6. In addition, the present technology is applicable to the case where the number of pixels 51 disposed in the row direction (horizontal direction) is different from the number of pixels 51 disposed in the column direction (perpendicular direction) like the unit element 37C illustrated in FIG. 7. In addition, needless to say, the present technology is also applicable to a unit element 37 including the number of pixels 51, the number being different from FIG. 5 to FIG. 7.

The positions of the QV amplifiers 55A to 55C in the unit elements A to C illustrated in FIG. 5 to FIG. 7 are mere examples. The present technology is not limited thereto. For example, in the unit element 37A illustrated in FIG. 5, the QV amplifier 55A-2 may be disposed below the QV amplifier 55A-1. In other words, the QV amplifier 55A-2 may be disposed at a crossing surrounded by the pixel 51A-2, the pixel 51A-3, the pixel 51A-5, and the pixel 51A-6.

With regard to the unit elements 37A to 37C illustrated in FIG. 5 to FIG. 7, the number of QV amplifiers 55 in the single unit element 37 is the same as the number of columns of the pixels 51 disposed in the unit element 37. For example, the pixels 51A are disposed in three rows and three columns in the unit element 37A illustrated in FIG. 5. Therefore, the unit element 37A includes the three QV amplifiers 55A.

In addition, for example, the pixels 51B are disposed in four rows and four columns in the unit element 37B illustrated in FIG. 6. Therefore, the unit element 37B includes four QV amplifiers 55B. In addition, for example, the pixels 51C are disposed in three rows and two columns in the unit element 37C illustrated in FIG. 7. Therefore, the unit element 37C includes two QV amplifiers 55C.

As described above, the number of QV amplifiers 55 disposed at crossings in the unit element 37 is the same as the number of columns of the pixels 51 disposed in the unit element 37. The crossings include no anode or cathode, and the crossings have a large area. Therefore, the crossings are regions with very good design efficiency, and the QV amplifiers 55 are disposed in such regions.

Note that, here, the examples in which the number of QV amplifiers 55 disposed at crossings in the unit element 37 is the same as the number of columns of the pixels 51 disposed in the unit element 37 are continuously described. However, for example, it is also possible to provide a configuration including a larger number of the QV amplifiers 55 than the number of columns of the pixels 51, such as a case where the number of pixels disposed in the row direction is large.

For example, in a unit element 37 in which the pixels 51 are disposed in ten rows and three columns, QV amplifiers 55 for reading out pixels 51 of five rows may be disposed in each column. In other words, the six QV amplifiers 55 may be disposed in the unit element 37.

In other words, the number of QV amplifiers 55 disposed in the single unit element 37 is at least the same as the number of columns of the pixels 51.

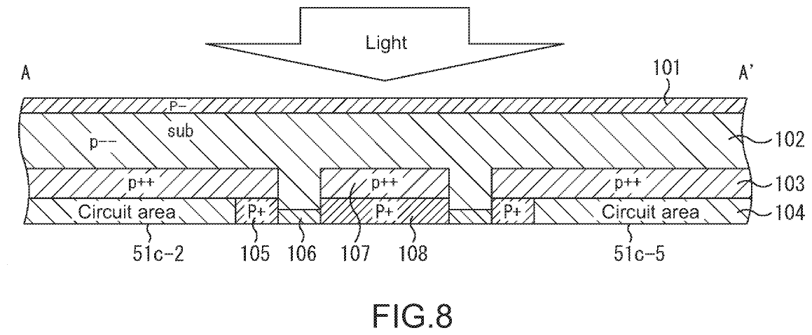

FIG. 8 is a cross-sectional view of a unit element 37. The cross-sectional view of the unit element 37 in FIG. 8 is a cross-sectional view of the unit element 37C in FIG. 7 taken along a line AA′ that overlaps the pixel 51C-3 and the pixel 51C-5, for example.

In FIG. 8, light is incident from an upper direction toward a lower direction. In other words, a top side of the unit element 37C illustrated in FIG. 8 is a light receiving side, and a bottom side thereof is an electrode side. The pixel 51C-2 and the pixel 51C-5 are configured in a manner that a P− layer 101, a P−− layer 102, a P++ layer 103, and a circuit area 104 are stacked in this order from the light receiving side. In addition, the pixel includes a P+ layer 105 as a side edge of the circuit area 104 in the same layer as the circuit area 104.

In addition, a cathode 106 is formed on the side edge of the P+ layer 105. In addition, a separating layer including a P++ layer 107 and a P+ layer 108 is formed between the pixel 51C-2 and the pixel 51C-5 (between the cathodes 106).

As illustrated in FIG. 8, the circuit areas 104 and the cathodes 106 are on the same plane, and amplifiers are formed inside the pixels. In the case of a singulated back-illuminated photodiode, a light receiving side does not include a region for blocking photoelectric conversion such as a pixel separating region or a light blocking region. In addition, the cathode 106 has a ring-like shape, a discrete shape (like a floating island), or a combination thereof.

A circuit is configured to be disposed in a gap between such cathodes 106. In the case of the back-illuminated photodiode, a circuit is formed on a front-surface side (electrode side). To separate the photodiode from the circuit in an up-down direction, highly concentrated impurities are diffused in an Epi layer. The crossing at which the QV amplifier 55 is disposed is a widest region of the P+ layer 108. Therefore, very good design efficiency is obtained. In addition, it is possible to design the unit element in a manner that circuits or the like other than the QV amplifiers 55 are provided at the P+ layer 108.

### <Circuit Configuration of Unit Element>

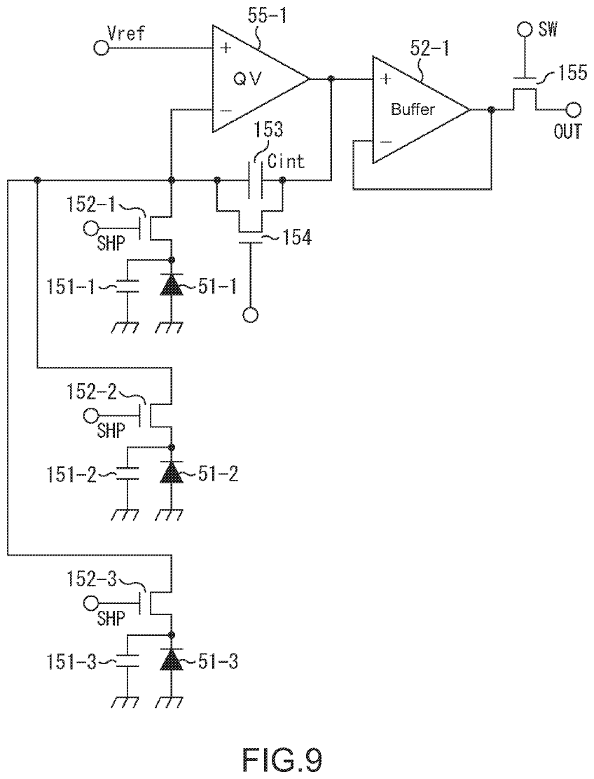

FIG. 9 is a diagram illustrating a circuit configuration of a unit element 37. FIG. 9 is a diagram for describing an example in which the three pixels 51 illustrated in FIG. 4 shares the QV amplifier 55 and the like.

The pixels 51-1 to 51-3 are connected to a negative terminal side of the QV amplifier 55-1 via switches 152-1 to 152-3 for adjusting respective readout timings. A capacitor 151-1 is connected to the pixel 51-1 in parallel. In a similar way, a capacitor 151-2 is connected to the pixel 51-2 in parallel, and a capacitor 151-3 is connected to the pixel 51-3 in parallel.

The switch 152-1 is a switch for adjusting a timing of transferring a signal from the pixel 51-1 (photodiode) to the QV amplifier 55-1. In a similar way, the switch 152-2 is a switch for adjusting a timing of transferring a signal from the pixel 51-2 (photodiode) to the QV amplifier 55-1, and the switch 152-3 is a switch for adjusting a timing of transferring a signal from the pixel 51-3 (photodiode) to the QV amplifier 55-1.

A reference power source supplies reference voltage Vref to a + terminal side of the QV amplifier 55-1. The − terminal of the QV amplifier 55-1 and an output terminal of the QV amplifier 55-1 are connected via a capacitor 153 that stores photoelectric charge. In addition, a transistor 154 for resetting the capacitor 153 is connected to both ends of the capacitor 153. The QV amplifier 55-1 performs IV conversion (current-voltage conversion).

Output from the QV amplifier 55-1 is supplied to a + terminal of the buffer 52-2. A − terminal of the buffer 52-2 is connected to an output terminal of the buffer 52-2. In addition, the output terminal of the buffer 52-2 is connected to a transistor 155 that adjusts an output timing. The transistor 155 outputs a signal, which has been temporarily held by the buffer 52-2, to a processing section (not illustrated) in a later stage at a predetermined timing. Note that, since the buffer 52-2 has a long wiring length, the buffer 52-2 is provided for low-impedance output.

For example, at a time t1, the switch 152-1 gets closed and a signal is transferred from the pixel 51-1 to the QV amplifier 55-1. After the transfer, the switch 152-1 gets opened.

After the QV amplifier 55-1, the signal from the pixel 51-1 is processed. In addition, at a time t2, the switch 152-2 gets closed and a signal is transferred from the pixel 51-2 to the QV amplifier 55-1. After the transfer, the switch 152-2 gets opened.

In addition, after the QV amplifier 55-1, the signal from the pixel 51-2 is processed. In addition, at a time t3, the switch 152-3 gets closed and a signal is transferred from the pixel 51-3 to the QV amplifier 55-1. After the transfer, the switch 152-3 gets opened.

As described above, the opening-closing timings of the switches 152-1 to 152-3 are adjusted, and signals are sequentially read out from the pixels 51-1 to 51-3. As illustrated in FIG. 4, the pixels 51-1 to 51-3 are pixels 51 disposed in the column direction (perpendicular direction). In such a way, the shared QV amplifier 55 sequentially reads out the signals from the pixels 51 disposed in the column direction.

### <Wiring and Terminals in Substrate>

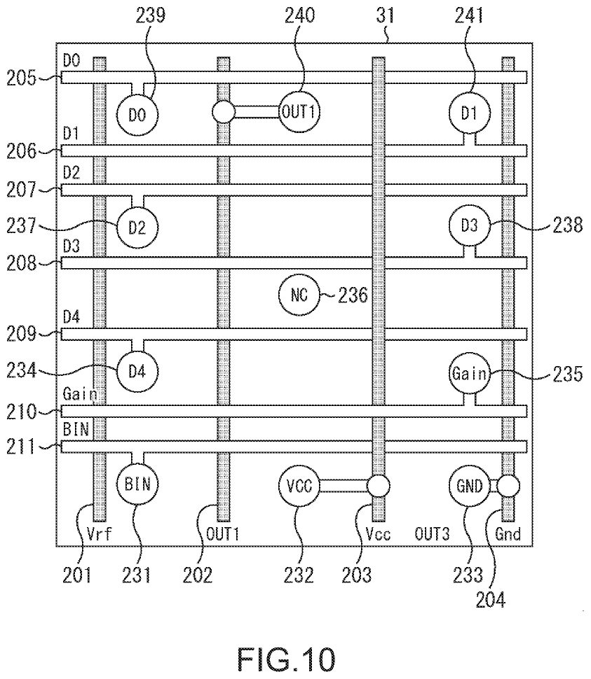

Next, wiring and terminals formed in the substrate 31 connected to the unit element 37 will be described. FIG. 10 is diagram illustrating an example of wiring and terminals formed in the substrate 31. The wiring and terminals illustrated in FIG. 10 are wiring and terminals for a single unit element 37. In the substrate 31, wiring and terminals for a plurality of the unit elements 37 connected to the substrate 31 are formed.

In the substrate 31, various kinds of power sources and output lines are formed in a vertical direction (perpendicular direction) of the drawing, and various kinds of control lines are formed in a lateral direction (horizontal direction) of the drawing. As the various kinds of power sources and output lines, a Vref signal line 201, an OUT1 signal line 202, a Vcc signal line 203, and a Gnd signal line 204 are formed. In addition, as various kinds of control lines, a DO control line 205, a D1 control line 206, a D2 control line 207, a D3 control line 208, a D4 control line 209, a Gain control line 210, and a BIN control line 211 are formed.

As the terminals, a BIN terminal 231, a Vcc terminal 232, a GND terminal 233, a D4 terminal 234, a Gain terminal 235, an NC terminal 236, a D2 terminal 237, a D3 terminal 238, a D0 terminal 239, an OUT1 terminal 240, and a D1 terminal 241 are formed in this order from the lower left side.

Note that, the wiring and terminals described above are mere examples. The present technology is not limited thereto. For example, a case where the positions of the wiring lines are changed and a case where the positions of the terminals are changed are also within the scope of application of the present technology.

If the plurality of pixels 51 is not configured to share the QV amplifier 55 and the like, the BIN terminal 231 to the D1 terminal 241 are prepared for each pixel 51. In the case where the plurality of pixels 51 is configured to share the QV amplifier 55 and the like, the plurality of pixels 51 can also share the terminals. Therefore, it is possible to reduce the number of terminals necessary for the single unit element 37.

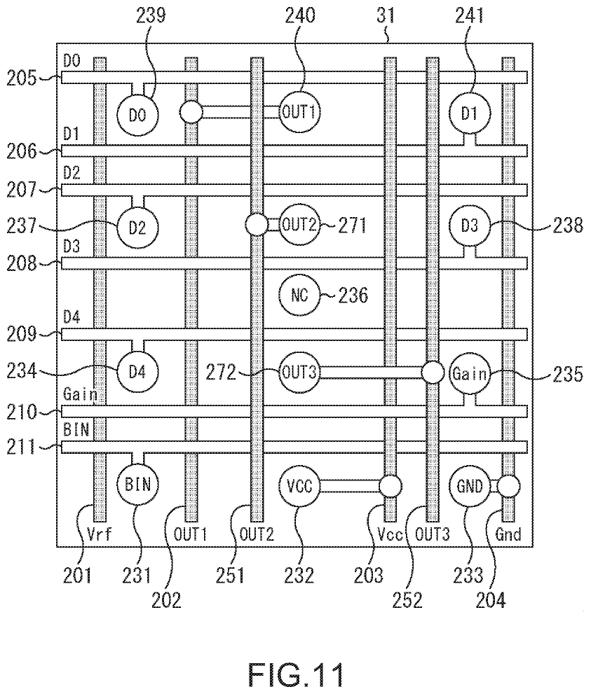

FIG. 11 is diagram illustrating another example of wiring and terminals formed in the substrate 31. The substrate 31 illustrated in FIG. 11 is different from the substrate 31 illustrated in FIG. 10 in that output lines are added to the substrate 31 illustrated in FIG. 11.

FIG. 10 illustrates the case where the output line in the substrate 31 is the single OUT1 signal line 202. However, in the substrate 31 illustrated in FIG. 11, three output lines which are the OUT1 signal line 202, an OUT2 signal line 251, and an OUT3 signal line 252 are formed. In addition, an OUT2 terminal 271 and an OUT3 terminal 272 are added as terminals connected to the signal lines. Since the three output lines are formed, it is possible to shorten time for output.

In a way similar to the substrate 31 illustrated in FIG. 10, it is also possible to reduce the number of terminals necessary for the single unit element 37 with regard to the substrate 31 illustrated in FIG. 11.

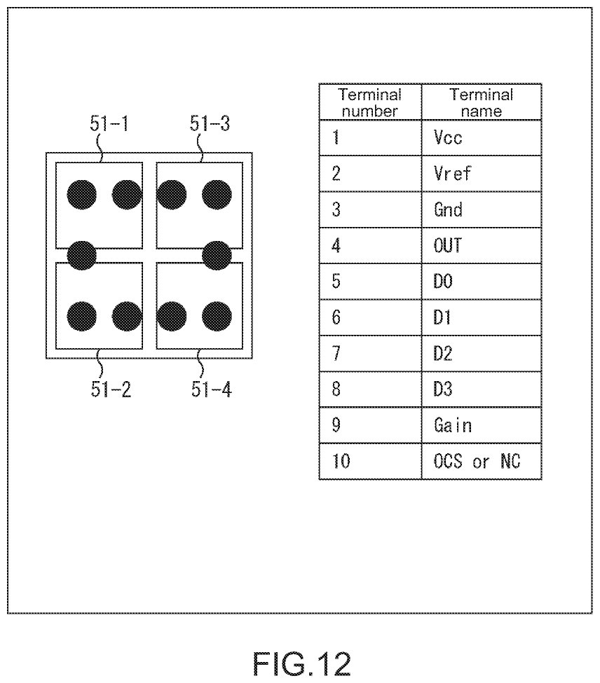

Even when the number of pixels 51 that share the QV amplifier 55 and the like increases, the number of terminals increases just slightly. Details thereof will be described here. As illustrated in a left side of FIG. 12, it is assumed that four pixels 51 share the QV amplifier 55 and the like. In FIG. 12, the pixels 51-1 to 51-4 are configured to share the QV amplifier 55 although the QV amplifier 55 and the like are not illustrated.

Note that, the case where the four (=2×2) pixels share the single QV amplifier 55 will be described for an illustrative purpose. However, in the case where the present technology is applied as described above, the number of provided QV amplifiers 55 are the same as the number of columns of the pixels 51. Therefore, two QV amplifiers 55 are provided in the case where the single unit element 37 includes the four (=2×2) pixels.

In the case where the four pixels share the QV amplifier 55, 10 terminals are formed in the substrate 31 (not illustrated) as illustrated in a right side of FIG. 12 (with reference to dots in the left side of FIG. 12). As illustrated in FIG. 10, the 11 terminals are formed in the substrate 31 in the case where the nine pixels share the QV amplifier 55. In other words, even in the case where the number of share pixels is increased from four to nine, the number of terminals increases only by one.

In addition, the added terminal is the D4 terminal 234. The terminals such as D0 to D4 terminals are connected to the signal lines that transfer signals of 0 or 1. As illustrated in FIG. 12, operation of article 2-4 is possible in the case where four terminals which are the D0 to D3 terminals are prepared. As illustrated in FIG. 10, operation of article 2-5 is possible in the case where five terminals which are the D0 to D4 terminals are prepared. As described above, the number of operations gets doubled when one D terminal is added.

As described above, even when the number of share pixels increases, the number of added terminals is less than the number of added pixels. Therefore, even in the case where the number of share pixels increases, the number of terminals does not need to be increased as much. Accordingly, in this respect, it is also possible to reduce the number of terminals because the pixels share structural elements.

When the number of terminals is reduced, it is possible to dispose the terminals while keeping distances from each other. The terminals are connected to bumps (the solder layer 36, FIG. 2). Therefore, a distance between the bumps is short when a distance between the terminals is short.

When the distance between the bumps is short, there is a high possibility that the bumps come into contact with each other. When the distance between the terminals is long, it is possible to reduce the possibility that the bumps come into contact with each other.

In addition, in the case where the distance between the bumps is long, it is possible to reduce a possibility that a bump comes into contact with another bump even when the sizes of the bumps are large. When the sizes of the bumps are large, it is possible to make stronger connections between the terminals and the bumps.

Therefore, it is possible to increase reliability of the light-receiving device 30 when the number of terminal is reduced and enough distances between the terminals are kept.

According to the present technology, it is possible to further increase reliability of the light-receiving device 30 because of the following reason.

In the case where the light-receiving device 30 is applied to a device for detecting radiation such as an α ray, a β ray, a γ ray, or an X ray, it is necessary to take into consideration effects of the radiation. When a large amount of radiation enters, electric charge caused and generated by ionization effect of the radiation forms fixed charge and an interface state, and deteriorates characteristics of elements. For example, this causes leakage among the transistors. Since the QV amplifier 55 and the like include a plurality of transistors, the cause of leakage among the transistors is preferably removed.

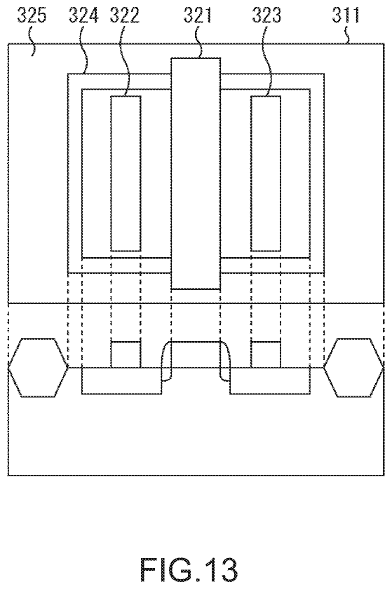

As a countermeasure against the above-described matter, it is conceived that an offset region is prepared in a transistor 311 as illustrated in FIG. 13. FIG. 13 is a diagram illustrating a plan view and a cross-sectional view of the transistor 311. The transistor 311 includes a gate 321, a source 322, and a drain 323. In addition, LOCal Oxidation of Silicon (LOCOS) 325 for separating elements is formed in an outer periphery of the transistor 311.

In addition, an offset 324 is formed between the source 322 (drain 323) and the LOCOS 325. Since such an offset 324 is provided, it is possible to prevent leakage from the LOCOS 325.

In addition, although not illustrated, concentration of the offset 324 may be increased by performing ion implantation of boron (B), and a separation characteristic between the transistors may be improved.

In addition, although not illustrated, the transistor may be configured in a manner that the transistor has a ring-like shape, a distance between the source 322 and the drain 323 increases, and the leakage is prevented.

Since the transistor 311 is configured in a manner that the leakage is prevented as described above, it is possible to reduce effects of the leakage. However, for example, the size of the transistor 311 itself increases in the case where the offset 324 is provided in the transistor 311 as illustrated in FIG. 13.

For example, in the case of another configuration, that is, in the case where the transistor has a ring-like shape, the size of the transistor 311 itself increases. In other words, when the transistor 311 has a large size, it is possible to reduce leakage.

Since the QV amplifier 55 includes the plurality of transistors 311, the size of the QV amplifier 55 gets larger when the size of the transistor 311 gets larger. In other words, if a region allocated to the QV amplifier 55 in the unit element 37 is large, it is possible to increase the sizes of the transistors 311 included in the QV amplifier 55. Therefore, it is possible to improve radiation resistance.

As described above, according to the present technology, it is possible to dispose the QV amplifier 55 in the region of the crossing formed by disposing the pixels 51. In addition, since the region of the crossing is a relatively large region, it is possible to dispose the QV amplifier 55 with a sufficient size as a result. This enables improvement in radiation resistance of the QV amplifier 55.

In addition, it is possible to dispose the buffer 52, the constant-current supply 53, and the decoder 54 in a region other than the crossing. In addition, they are shared by the plurality of pixels 51. Therefore, it is possible to reduce the number of structural elements to be disposed and it is possible to enlarge the region in which they are disposed. Accordingly, it is also possible to improve radiation resistance of the buffer 52, the constant-current supply 53, the decoder 54, and the like.

In addition, it is not necessary to reduce the sizes of the pixels 51 even when the sizes of the buffer 52, the constant-current supply 53, the decoder 54, and the QV amplifier 55 are large. Therefore, it is also possible to prevent reduction in sensitivity.

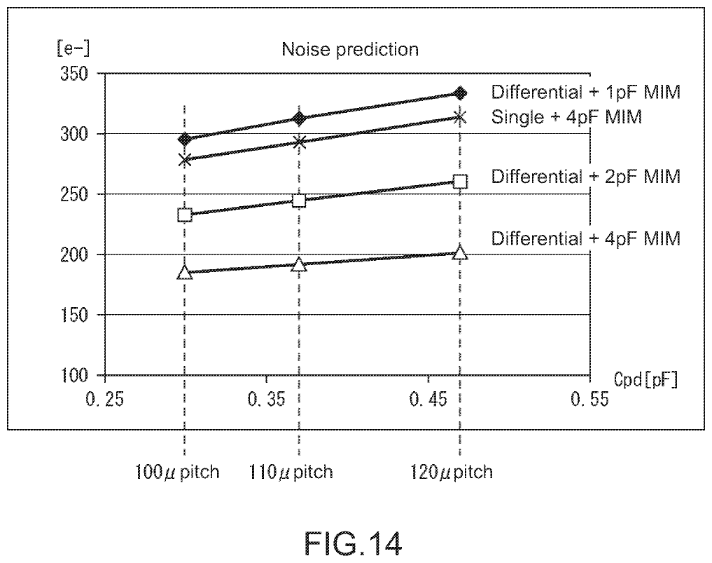

In addition, according to the present technology, it is also possible to reduce noise. With reference to FIG. 14, the noise reduction will be described. In the graph illustrated in FIG. 14, a horizontal axis represents capacitance, and a vertical axis represents an amount of noise.

To reduce the noise, the capacitor is often mounted as typified by metal insulator metal (MIM). Parasitic capacitance reduces as a pitch gets narrowed. Therefore, it is expected to improve the noise reduction effect. For example, FIG. 14 illustrates noise data obtained when a differential 1 pf capacitor, a single 4 pF capacitor, a differential 2 pf capacitor, or a differential 4 pf capacitor is mounted.

With reference to FIG. 14, a characteristic less than 200-e is expected when capacitance increases. As described above, the characteristic is improved since the area is enlarged. In other words, in this case, for example, an effect of reducing noise is also obtained by enlarging the area capable of mounting the QV amplifiers 55.

As described above, according to the present technology, it is possible to sequentially read out the pixels 51 disposed in the unit element 37 in the column direction. As described above with reference to FIG. 3, the plurality of unit elements 37 is disposed above the substrate 31. Each of the plurality of unit elements 37 disposed above the substrate 31 is unified in a readout direction, that is, the column direction.

For example, in the case where the unit elements 37-1 to 37-9 are disposed above the substrate 31 as illustrated in FIG. 3, the unit elements 37-1 to 37-9 may have the same size. For example, in each of the unit elements 37, nine (=3×3) pixels 51 are disposed. Alternatively, the unit elements 37 may include unit elements 37 with different sizes (number of pixels).

As described above, the unit elements 37 each have the unified readout direction. Accordingly, even in the case where the unit elements 37 include a unit element 37 having the different number of pixels from the other unit elements 37, they have the same readout direction. Therefore, it is possible to prevent processes from getting complicated.

In addition, for example, in the case where the size of the substrate 31 is limited, it is also possible to combine and dispose unit elements 37 with different sizes in a manner that the unit elements 37 fit the limited size of the substrate 31.

In addition, for example, the unit element 37 is manufactured by singulating a circular wafer. Note that, it is also possible to obtain a relatively large unit element 37 from a center of the circular wafer, and obtain relatively small unit elements 37 from the circumference. Accordingly, it is possible to effectively manufacture the unit elements 37 by using a wafer.

According to the present technology, it is possible to read out respective pixels in the perpendicular vertical direction (without changing the order of numerical values). In addition, it is possible to form the unit elements without deteriorating light receiving sensitivity and characteristics in resolution.

In addition, it is possible to obtain X-ray resistance and reduce noise (increase capacitance), and it is possible to widen bump pitches with regard to the number of pixels/the number of terminals. This improves reliability.

Note that, the above-described embodiment has described that signals are sequentially read out from the pixels disposed in the vertical direction (perpendicular direction, column direction). However, the present technology is also applicable to a case where signals are sequentially read out from pixels disposed in a lateral direction (horizontal direction, row direction), for example. In other words, according to the present technology, signals can be configured to be sequentially read out from pixel disposed in a same direction.

In the present specification, a system represents the entire device including a plurality of devices.

Note that, the effects described in the present specification are merely illustrative, and the present technology is not limited thereto. There may be other effects.

Note that, the embodiment of the present technology is not limited to the above-described embodiment, and various modifications are possible without departing from the gist of the present technology.

Note that, the present technology can employ the following configurations.
(1)

A light-receiving device including

a plurality of unit elements disposed above a substrate, each of the unit elements including
a plurality of pixels disposed in m number of rows and n number of columns, and
a readout section that sequentially reads out signals from a plurality of pixels disposed in a column direction among the plurality of pixels,

in which the number of readout sections is at least the same as the number of columns.
(2)

The light-receiving device according to (1),

in which the readout section includes a QV amplifier.
(3)

The light-receiving device according to (2),

in which the QV amplifier is disposed at a crossing surrounded by four pixels in two rows and two columns among the plurality of pixels.
(4)

The light-receiving device according to (2),

in which the QV amplifier is disposed at a center of a region in which four pixels are disposed in two rows and two columns among the plurality of pixels.
(5)

The light-receiving device according to any of (2) to (4), in which

the read out section further includes a buffer, and

the buffer is disposed in a region between the pixels.
(6)

The light-receiving device according to any of (1) to (5),

in which the m is three or more, and the n is two or more.
(7)

The light-receiving device according to any of (1) to (6),

in which the unit element includes silicon.
(8)

The light-receiving device according to any of (1) to (7),

in which the light-receiving device detects radiation.

### REFERENCE SIGNS LIST

30 light-receiving device
31 substrate
32, 33 insulating film
34 wiring layer
35 UBM
36 solder layer
37 unit element
38 wiring substrate
51 pixel
52 buffer
53 constant-current supply
54 decoder
QV amplifier

1. A light-receiving device comprising
a plurality of unit elements disposed above a substrate, each of the unit elements including
a plurality of pixels disposed in m number of rows and n number of columns, and
a readout section that sequentially reads out signals from a plurality of pixels disposed in a column direction among the plurality of pixels,
wherein the number of readout sections is at least the same as the number of columns.

2. The light-receiving device according to claim 1,
wherein the readout section includes a QV amplifier.

3. The light-receiving device according to claim 2,
wherein the QV amplifier is disposed at a crossing surrounded by four pixels in two rows and two columns among the plurality of pixels.

4. The light-receiving device according to claim 2,
wherein the QV amplifier is disposed at a center of a region in which four pixels are disposed in two rows and two columns among the plurality of pixels.

5. The light-receiving device according to claim 2, wherein
the read out section further includes a buffer, and
the buffer is disposed in a region between the pixels.

6. The light-receiving device according to claim 1,
wherein the m is three or more, and the n is two or more.

7. The light-receiving device according to claim 1,
wherein the unit element includes silicon.

8. The light-receiving device according to claim 1,
wherein the light-receiving device detects radiation.
